(19) United States
(12) Patent Application Publication
(10) Pub. No.: US 2012/0152603 A1
(43) Pub. Date: Jun. 21, 2012

(54) PRINTED CIRCUIT BOARD INCLUDING AT LEAST ONE LAYER

(75) Inventors: Ki Jae SONG, Paju-si (KR); Woo Ik Park, Cheonan-si (KR)

(73) Assignee: Samsung Electronics Co., Ltd., Suwon-si (KR)

(21) Appl. No.: 13/314,494

(22) Filed: Dec. 8, 2011

(30) Foreign Application Priority Data
Dec. 15, 2010 (KR) 10-2010-0128465

(51) Int. Cl. H05K 1/16; H05K 3/46; H05K 1/00

(52) U.S. Cl. 174/260; 174/250; 29/846

(57) ABSTRACT

A printed circuit board (PCB) for transmitting a signal that includes a first layer, and a second layer disposed on the first layer. The first layer includes a first signal line to transmit the signal, and a first ground line and a second ground line disposed at both sides of the first signal line to be apart from the first signal line by a first distance. The second layer includes a second signal line to transmit the signal, and a third ground line and a fourth ground line disposed at both sides of the second signal line to be apart from the second signal line by a second distance. The third ground line or the fourth ground line is disposed on the first signal line.

### CROSS-REFERENCE TO RELATED APPLICATIONS

This application claims priority under 35 U.S.C. §119(a) from Korean Patent Application No. 10-2010-0128465 filed on Dec. 15, 2010, the disclosure of which is hereby incorporated by reference in its entirety.

### BACKGROUND

1. Field

The inventive concept relates to printed circuit boards (PCBs), and more particularly, to a PCB for increasing the yield of a multi-layer packaging PCB.

2. Description of the Related Art

A semiconductor printed circuit board (PCB) is a basic and indispensable part of all electronic equipment. The PCB allows electrical signals to be exchanged between devices and is a supporting structure.

A semiconductor PCB manufactured according to a semiconductor manufacturing process is tested so as to check whether it normally operates according to design specifications thereof.

Advances in semiconductor technology have led to a change in semiconductor PCBs to be tested. That is, semiconductor PCBs become smaller in size, but become larger in thickness since multi-layer packaging has come into widespread use to improve an integration degree thereof. Such changes have resulted in, for example, the following: (i) as the size of a semiconductor PCB becomes smaller, fine pitches between solder balls should be reduced, and (ii) when the multi-layer packaging is performed, a semiconductor PCB is increased in terms of thickness, and thus, via drill size should also be increased.

However, if the fine pitches are reduced, the via drill size should also be reduced. Accordingly, there is a contradiction between the above items (i) and (ii).

### SUMMARY

According to some exemplary embodiments of the present general inventive concept, there is provided a printed circuit board (PCB) for transmitting a signal, the printed circuit board including a first layer, and a second layer disposed on the first layer. The first layer may include a first signal line to transmit the signal, and a first ground line and a second ground line disposed at both sides of the first signal line and spaced apart from the first signal line by a first distance. The second layer may include a second signal line to transmit the signal, and a third ground line and a fourth ground line disposed at both sides of the second signal line and spaced apart from the second signal line by a second distance. The third ground line or the fourth ground line may be disposed above the first signal line.

According to another exemplary embodiment of the present general inventive concept, the first distance or the second distance may be adjusted to perform an impedance matching. Further, the impedance matching may be provided at, for example, 50Ω.

According to another exemplary embodiment of the present general inventive concept, the first through the fourth ground lines may be formed to have a circle-hole mesh pattern.

According to another exemplary embodiment of the present general inventive concept, the PCB may further include a third layer disposed below the first layer. Here, the third layer may include a third signal line to transmit the signal and a fifth ground line and a sixth ground line disposed at both sides of the third signal line and spaced apart from the third signal line by a third distance. Further, the fifth ground line or the sixth ground line may be disposed below the first signal line

According to other exemplary embodiments of the present general inventive concept, the first signal line may form a first capacitance together with the first ground line and the second ground line. Similarly, the first signal line may form a second capacitance together with the third ground line or the fourth ground line. In these cases, an impedance matching may be performed by adjusting a value of the first capacitance by changing the first distance. Further, the value of the second capacitance may be less than the value of the first capacitance. Additionally, each of the first signal line and the second signal line may include an inductance component.

According to another exemplary embodiment of the present general inventive concept, the printed circuit board may have a multi-layered structure including the first through the third layers.

According to another exemplary embodiment of the present general inventive concept, each of the first through the fourth ground lines may include a metal line return path. In this case, the metal return paths of the first and second ground lines may be formed between the circle-hole mesh patterns of the first and second ground lines and the first signal line. Similarly, the metal return paths of the third and fourth ground lines may be formed between the circle-hole mesh patterns of the third and fourth ground lines and the second signal line.

According to other exemplary embodiments of the general inventive concept, there is provided a method of manufacturing a printed circuit board for transmitting a signal, the method including forming a first layer, and forming a second layer on the first layer. The first layer may include a first signal line to transmit the signal, and a first ground line and a second ground line disposed at both sides of the first signal line and spaced apart from the first signal line by a first distance. The second layer includes a second signal line to transmit the signal, and a third ground line and a fourth ground line disposed at both sides of the second signal line and spaced apart from the second signal line by a second distance. The third ground line or the fourth ground line is disposed above the first signal line.

According to another exemplary embodiment of the present general inventive concept, the printed circuit board may include a first layer having at least one first ground line and at least one first signal line to transmit the signal. Here, the at least one first signal line may be spaced a first distance from the at least one first ground line. The printed circuit board may also include a second layer disposed on the first layer in a stacked direction and may include at least one second ground line and at least one second signal line to transmit the signal. Here, the at least one second signal line may be spaced a second distance from the at least one first ground line. Further, the at least one second ground line and the at least one second signal line may overlap the at least one first signal line and the at least one first ground line in the stacked direction, respectively. That is, the signal lines and ground lines of each of the various layers may be alternately arranged with respect to the signal lines and ground lines of an adjacent layer.

According to another exemplary embodiment of the present general inventive concept, the at least one first ground line and the at least one second ground line may be formed in a circle-hole mesh pattern.

Here, each of the at least one first ground line and the at least one second ground line may include a metal line return path. The metal return path of the at least one first ground line may formed between the circle-hole mesh pattern of the at least one first ground line and the at least one first signal line. Similarly, the metal return path of the at least second ground line may be formed between the circle-hole mesh pattern of the at least second ground line and the at least one second signal line.

According to another exemplary embodiment of the present general inventive concept, a first capacitance may be formed between the at least first signal line and the at least one first ground line, and a second capacitance may be formed between the at least first signal line and the at least one second ground line. Here, an impedance matching may be performed by adjusting a value of the first capacitance or a value of the second capacitance by changing the first distance or the second distance, respectively. Further, the value of the second capacitance may be less than the value of the first capacitance.

According to another exemplary embodiment of the present general inventive concept, the second capacitance may be formed between the metal return path of the at least second ground line and the at least first signal line.

Additional aspects and advantages of the present general inventive concept will be set forth in part in the description which follows and, in part, will be obvious from the description, or may be learned by practice of the general inventive concept.

### BRIEF DESCRIPTION OF THE DRAWINGS

These and/or other aspects and advantages of the present general inventive concept will become apparent and more readily appreciated from the following description of the exemplary embodiments, taken in conjunction with the accompanying drawings of which:

FIG. 1 is a conceptual diagram of a printed circuit board (PCB) according to some exemplary embodiments of the present general inventive concept;

FIGS. 2A-2C are various perspective views illustrating the PCB of FIG. 1;

FIG. 3 is a plane view of a first layer illustrated in FIG. 1; and

FIGS. 4A-4C illustrate performing impedance matching in a PCB, according to some exemplary embodiments of the present general inventive concept.

### DETAILED DESCRIPTION OF EXEMPLARY EMBODIMENTS

Reference will now be made in detail to the exemplary embodiments of the present general inventive concept, examples of which are illustrated in the accompanying drawings, wherein like reference numerals refer to the like elements throughout. The embodiments are described below in order to explain the present general inventive concept while referring to the figures. The general inventive concept may, however, be embodied in many different forms and should not be construed as limited to the exemplary embodiments set forth herein.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular exemplary embodiments only and is not intended to be limiting of the general inventive concept. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

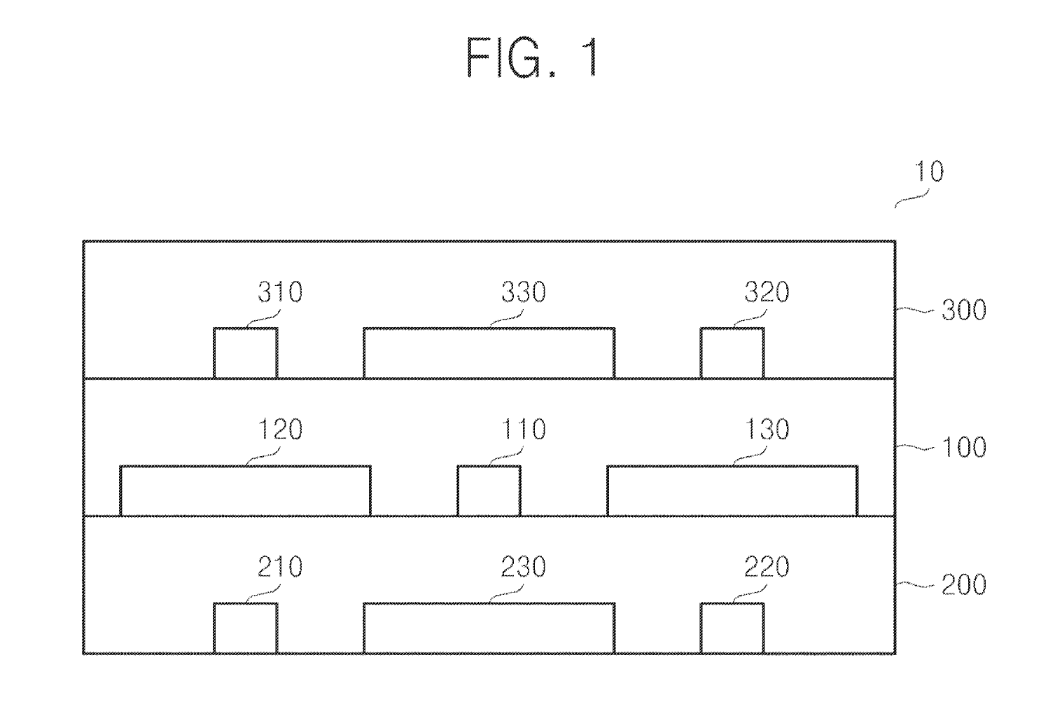

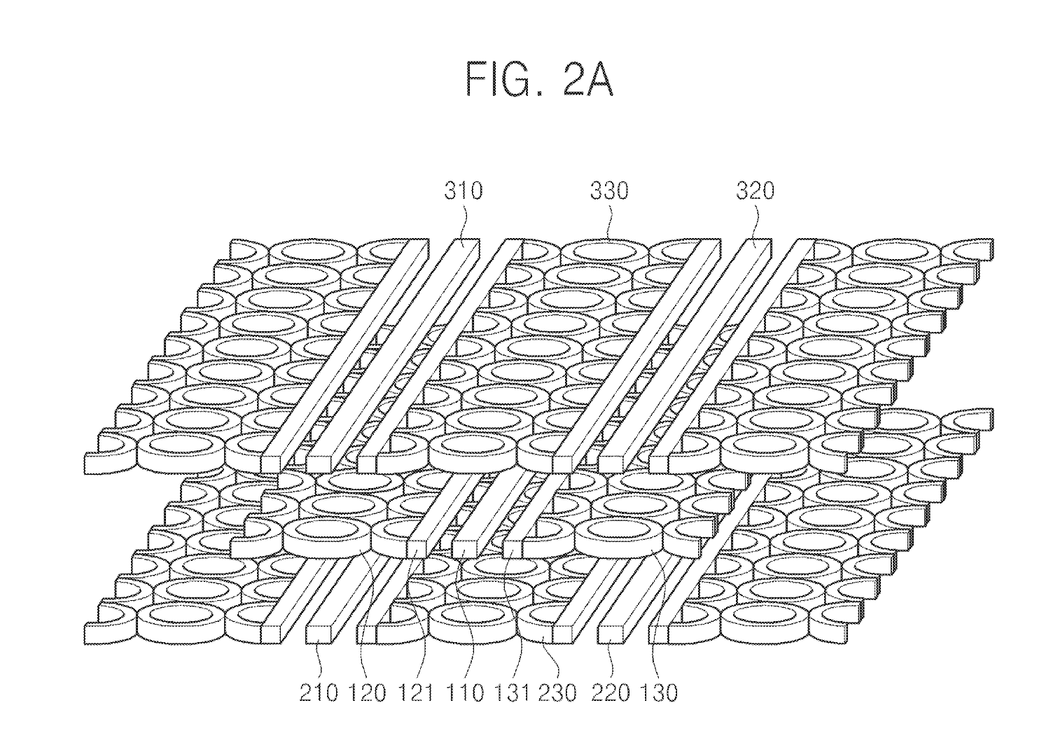

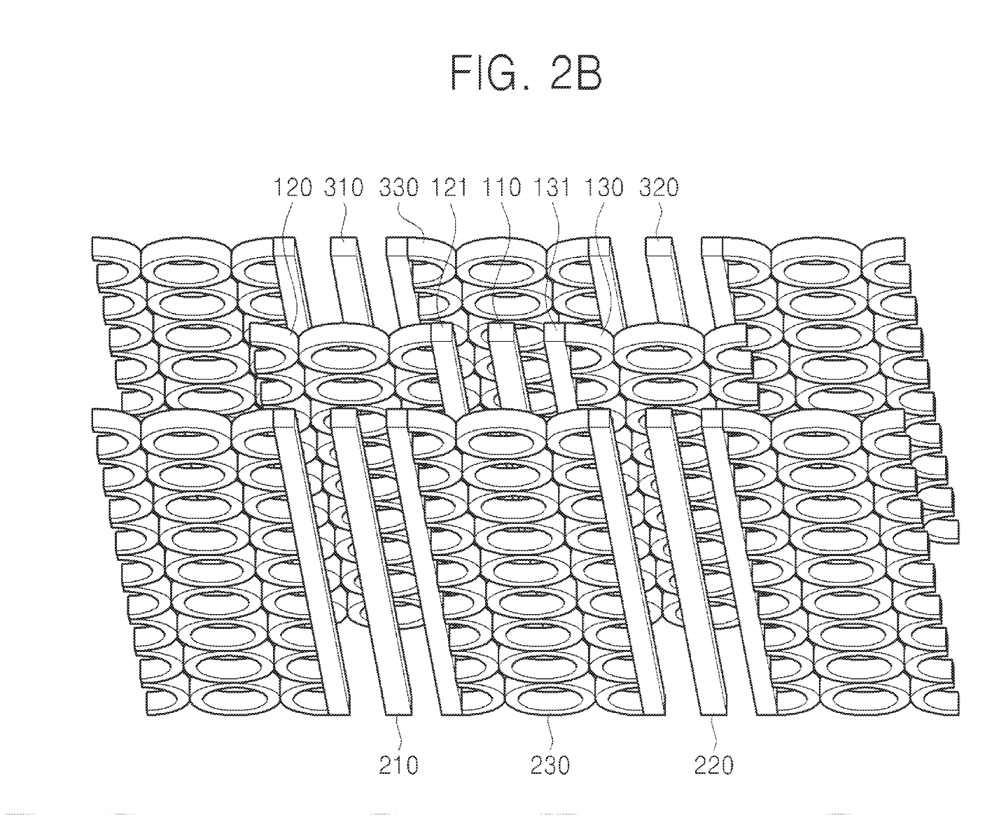

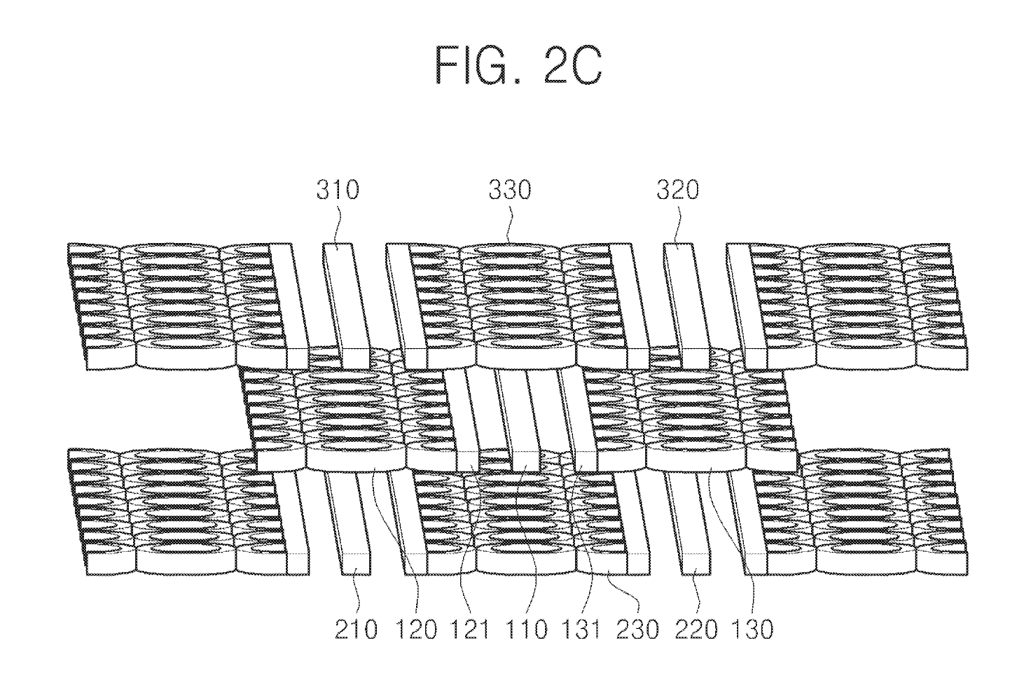

FIG. 1 is a conceptual diagram of a printed circuit board (PCB) 10 according to some exemplary embodiments of the present general inventive concept. FIGS. 2A through 2C are various perspective views illustrating the PCB 10 of FIG. 1.

Referring to FIG. 1, the PCB 10 may have a multi-layered structure. For example, the PCB 10 may include a first layer 100, a second layer 200, and a third layer 300. The first layer 100 may be disposed between the second layer 200 and the third layer 300.

The PCB 10 having the multi-layered structure may have a stacked structure of a plurality of layers, and may be manufactured by stacking a plurality of substrates and bonding the plurality of substrates with one another. The multi-layered PCB may be used as a route for transmitting a signal, e.g., a radio frequency (RF) signal.

The first layer 100 includes a 1-1 signal line 110, a 1-1 ground line 120, and a 1-2 ground line 130. The second layer 200 includes a 2-1 signal line 210, a 2-2 signal line 220, and a 2-1 ground line 230. The third layer 300 includes a 3-1 signal line 310, a 3-2 signal line 320, and a 3-1 ground line 330.

Although FIG. 1 illustrates that each layer includes one or two signal lines, and one or two ground lines, the general inventive concept is not limited thereto and a plurality of a signal line and a plurality of ground lines may be included in each layer in an alternate pattern.

Each of the 1-1 signal line 110, the 1-1 ground line 120, the 1-2 ground line 130, the 2-1 signal line 210, the 2-2 signal line 220, the 2-1 ground line 230, the 3-1 signal line 310, the 3-2 signal line 320, and the 3-1 ground line 330 may be formed of metal that may conduct an electrical signal, e.g., aluminum or copper.

The 1-1 signal line 110, the 2-1 signal line 210, the 2-2 signal line 220, the 3-1 signal line 310, and the 3-2 signal line 320 included in the first layer 100 to the third layer 300 may conduct a signal, e.g., an RF signal. Here, the signal may be an electrical signal having a certain frequency.

In the first layer 100, in order to apply a ground voltage, the 1-1 ground line 120 and the 1-2 ground line 130 are respectively disposed at opposite sides of the 1-1 signal line 110 so to be spaced apart from the 1-1 signal line 110 by a predetermined distance. That is, the 1-1 signal line 110 is disposed between the 1-1 ground line 120 and the 1-2 ground line 130, and the 1-1 signal line 110 is spaced apart from both the 1-1 ground line 120 and the 1-2 ground line 130. Further, the distance between the 1-1 signal line 110 and the 1-1 ground line 120, and the distance between the 1-1 signal line 110 and 1-2 ground line 130 may be equal or may be different from one another.

The structures of the second layer 200 and the third layer 300 are similar to those of the first layer 100. For example, 2-1 ground line 230 is disposed between 2-2 signal line 210 and 2-2 signal line 220, and the 2-1 ground line 230 is spaced apart from both the 2-2 signal line 210 and 2-2 signal line 220. Similarly, the 3-1 ground line 300 is disposed between, and spaced apart from, 3-1 signal line 310 and 3-2 signal line 320. Further, the 2-1 ground line 230 and the 3-1 ground line 330 are respectively disposed below and above the 1-1 signal line 110 in a stacked direction, as illustrated in FIG. 1.

Likewise, the 1-1 ground line 120 is disposed above the 2-1 signal line 210 and below the 3-1 signal line 310, and the 1-2 ground line 130 is disposed above the 2-2 signal line 220 and below the 3-2 signal line 320 in the stacked direction.

Referring to FIGS. 1 through 2C, each of the first layer 100 to the third layer 300 may have a coplanar wave guide (CPW) structure.

In each layer having the CPW structure, ground lines are not disposed above and below a signal line but are disposed at both sides of the signal line, as illustrated in FIG. 1.

When the CPW structure is used, it is possible to design a PCB having a relatively thin thickness because the ground lines are disposed at both sides of the signal line.

In the case of a PCB that transmits a digital signal at high speeds, consideration is given to impedance matching. However, if a PCB employs only the CPW structure, ground lines are disposed not only at both sides of the signal line of each layer, but ground lines of other layers stacked above and below each layer are also above and below each of the signal lines. As a result, impedance matching is not easily performed due to the orientation of the ground lines above and below each of the signal lines.

In a PCB according to an exemplary embodiment of the general inventive concept, the ground lines of the first layer 100 through the third layer 300, e.g., the 1-1 ground line 120, the 1-2 ground line 130, the 2-1 ground line 230, and the 3-1 ground line 330, may be formed in a circle-hole mesh pattern, as illustrated in FIGS. 2A through 2C.

In order to reduce and/or prevent distortion from occurring in a signal to be transmitted, impedance matching may be provided by the orientation of the ground lines disposed at both sides of the signal lines (e.g. 1-1 signal line 110, 2-1 signal line 210, 2-2 signal line 220, 3-1 signal line 310, and 3-2 signal line 320). For example, the 1-1 ground line 120 and the 1-2 ground line 130 may be disposed at both sides of the 1-1 signal line 110, as illustrated in FIG. 1

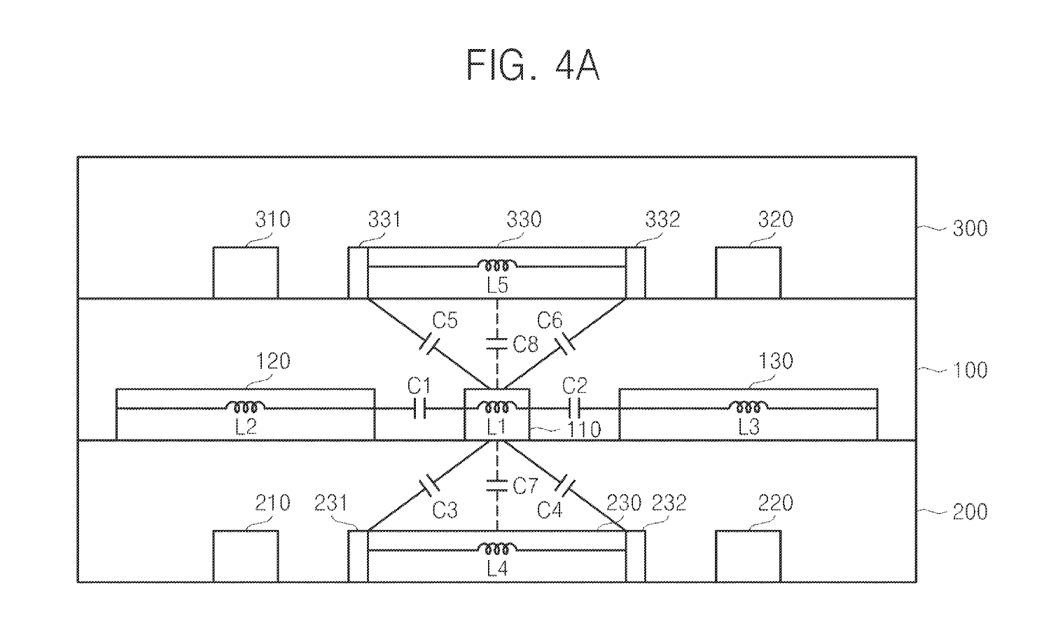

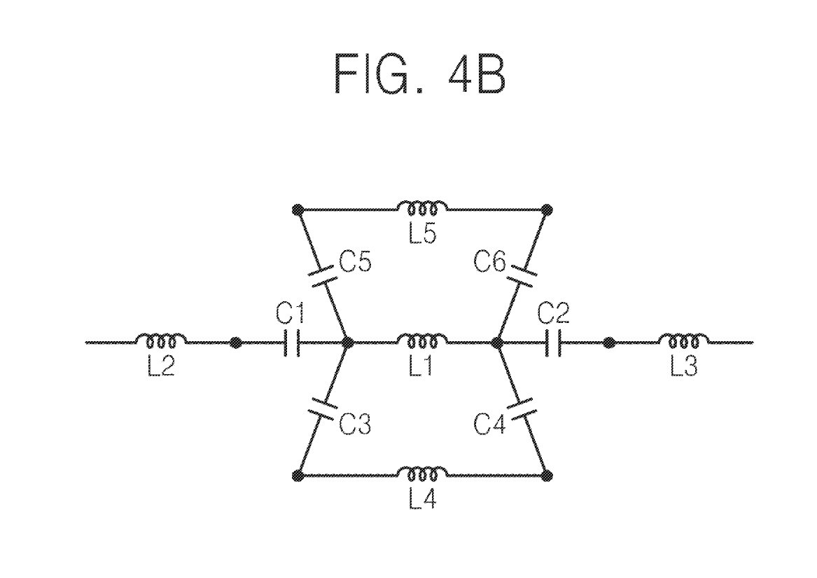

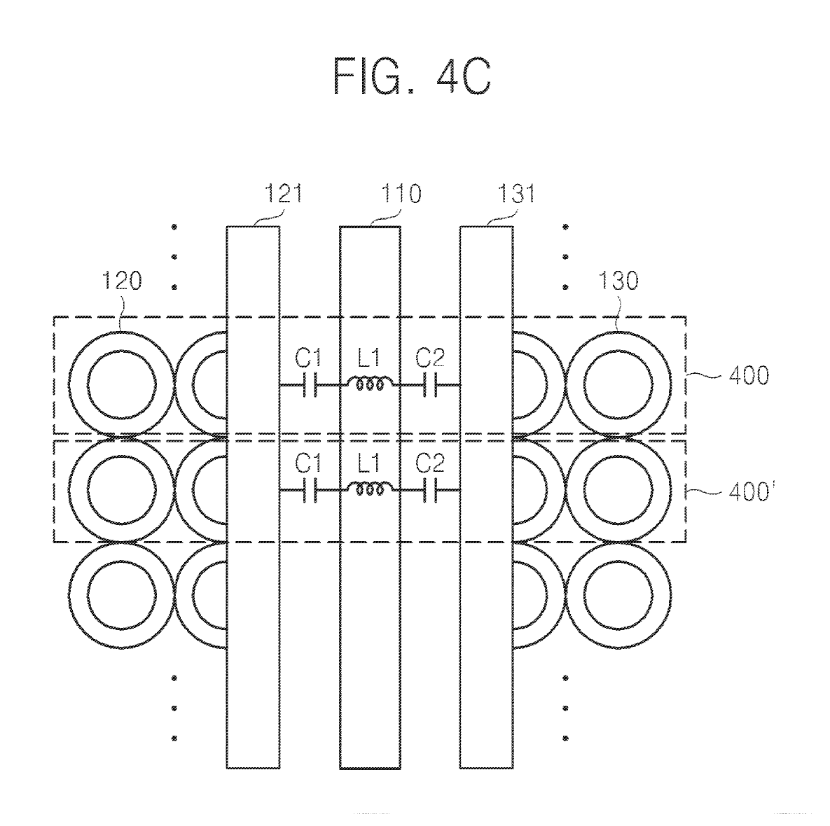

In this case, since the ground lines disposed below and above the signal lines (e.g., the 2-1 ground line 230 below the 1-1 signal line 110 and the 3-1 ground line 330 above the 1-1 signal line 110) are formed in the circle-hole mesh pattern, a high impedance is generated by the ground lines (2-1 ground line 230 and 3-1 ground line 330), and the ground lines disposed above and below the signal lines will have little or no influence on an impedance value used for performing impedance matching. This will be described in more detail below with reference to FIGS. 4A through 4C.

The impedance matching may be performed between a signal line (e.g., 1-1 signal line 110) and the ground lines (e.g., 2-1 ground line 230 and 3-1 ground line 330), which are disposed at opposing sides of the signal line. In this case, for example, a characteristic impedance value for performing impedance matching may be 50Ω but the general inventive concept is not limited thereto.

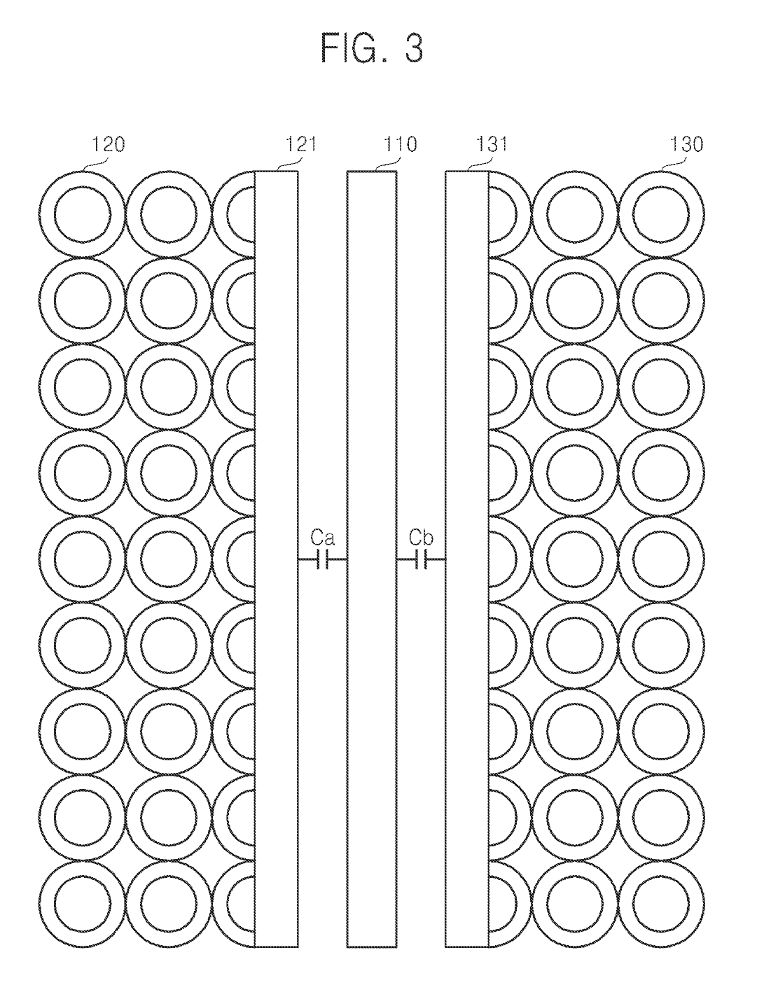

FIG. 3 is a plane view of the first layer 100 of FIG. 1. Referring to FIG. 3, the 1-1 ground line 120 and the 1-2 ground line 130 are formed in the circle-hole mesh pattern as described above. For a return path, the 1-1 ground line 120 and the 1-2 ground line 130 may respectively include a first metal line 121 and a second metal line 131 at an end thereof.

The 1-1 signal line 110 is disposed adjacent to the first metal line 121 and the second metal line 131. The 1-1 signal line 110 may respectively form capacitance, for example, Cₐ and C_{b}, together with the first metal line 121 and the second metal line 131.

Impedance matching may be provided, for example, at 500 between the 1-1 signal line 110 and each of the capacitances Cₐ and C_{b} by using an inductance value of the 1-1 signal line 110 and an inductance value of the 1-1 ground line 120 or the 1-2 ground line 130. This will now be described in detail with reference to FIGS. 4A through 4C.

FIGS. 4A through 4C illustrate performing impedance matching in a PCB, according to some exemplary embodiments of the present general inventive concept. FIG. 4B illustrates an equivalent circuit with reference to the 1-1 signal line 110 of FIG. 4A.

Specifically, FIG. 4B illustrates capacitances or inductances formed by unit lengths of signal lines and ground lines of FIG. 4A, for example, unit lengths of a 1-1 signal line 110, a 2-1 signal line 210, a 2-2 signal line 220, a 3-1 signal line 310, and a 3-2 signal line 320, and a 1-1 ground line 120, a 1-2 ground line 130, a 2-1 ground line 230, and a 3-1 ground line 330.

FIGS. 4A through 4C are described below with reference to the 1-1 signal line 110.

Referring to FIG. 4B, the 1-1 signal line 110 and ground lines adjacent thereto, e.g., the 1-1 ground line 120, the 1-2 ground line 130, the 2-1 ground line 230, and the 3-1 ground line 330, may respectively have inductance components, for example, first through fifth inductance components L₁ through L₅.

More specifically, the 1-1 signal line 110 may have a first inductance component L₁, the 1-1 ground line 120 may have a second inductance component L₂, the 1-2 ground line 130 may have a third inductance component L₃, the 2-1 ground line 230 may have a fourth inductance component L₄, and the 3-1 ground line 330 may have a fifth inductance component L₅.

The 1-1 signal line 110 may form a first capacitance C₁ together with the 1-1 ground line 120 adjacent to one side thereof, and may form a second capacitance C₂ together with the 1-2 ground line 130 adjacent to another side thereof.

Because the ground lines (2-1 ground line 230 and 3-1 ground line 330) located above and below the 1-1 signal line 110 have a circle-hole structure, the 1-1 signal line 110 does not form opposite capacitances C₇ and C₃ between the ground lines below and above the 1-1 signal line. This is because the ground lines (2-1 ground line 230 and 3-1 ground line 330) have a circle-hole structure in which centers thereof are hollow.

Although the 1-1 signal line 110 does not form the opposite capacitances C₇ and C₈ together with the ground lines below and above the 1-1 signal line 110, the 1-1 signal line 110 may respectively form capacitances, for example, capacitances C₃, C₄, C₅, and C₆, together with metal lines 231, 232, 331, and 332 disposed at ends of the 2-1 ground line 230 and the 3-1 ground line 330. In this case, values of the capacitances C₃, C₄, Cₛ, and C₆ are significantly less than values of the opposite capacitances C₇ and C₈ because the distances between the 1-1 signal line 110 and the metal lines 231, 232, 331, and 332 are greater than the distances between the 1-1 signal line 110 and the 2-1 ground line 230 and between the 1-1 signal line 110 and the 3-1 ground line 330.

More specifically, for example, the 1-1 signal line 110 may form the third capacitance C₃ and the fourth capacitance C₄ together with the metal lines 231, 232 disposed at the ends of the 2-1 ground line 230, and may form the fifth capacitance C₅ and the sixth capacitance C₆ together with the metal lines 331, 332 disposed at the ends of the 3-1 ground line 330.

A characteristic impedance value of the 1-1 signal line 110 may be calculated by:

$${Z}_{o} = \sqrt{\frac{L}{C}} . \qquad ( 1 )$$

Equation (1) is an equation for calculating a characteristic impedance value of a lossless transmission line, in which ‘Zₒ’ denotes the characteristic impedance value, ‘L’ denotes an inductance per unit length, and ‘C’ denotes a capacitance per unit length.

For example, referring to FIG. 4C, if a unit length is 400 or 400′, then the inductance L may be determined by a first inductance L₁, and the capacitance C may correspond to the first capacitance C₁ or the second capacitance C₂.

Impedance matching is performed by using the 1-1 ground line 120 and the 1-2 ground line 130 at both sides of the 1-1 signal line 110. For example, the first inductance L₁ is proportional to the width of the 1-1 signal line 110. However a reduction of the width of the 1-1 signal line 110 is limited. For example, a minimum width of the 1-1 signal line 110 may be 60 microns. Thus, the impedance matching may be performed by adjusting the first capacitance C₁ or the second capacitance C₂. In particular, values of the first capacitance C₁ and the second capacitance C₂ may be adjusted by changing the distances between the 1-1 signal line 110 and the 1-1 ground line 120 and between the 1-1 signal line 110 and the 1-2 ground line 130.

Since the ground lines below and above the 1-1 signal line 110 (2-1 ground line 230 and 3-1 ground line 330) have the circle-hole mesh structure, a high impedance is generated in these ground lines (2-1 ground line 230 and 3-1 ground line 330), and thus the impedance matching is not influenced by these ground lines.

For example, values of the third capacitance C₃ to the sixth capacitance C₆ formed between the ground lines below and above the 1-1 signal line 110 (e.g., 2-1 ground line 230 and 3-1 ground line 330) are far less than values of the first capacitance C₁ and the second capacitance C₂ formed between the 1-1 signal line 110 and the 1-1 ground line 120 and between the 1-1 signal line 110 and the 1-2 ground line 130, respectively. This is because the distances between the 1-1 signal line 110 and the metal lines 231, 232, 331, and 332 at ends of the 2-1 ground line 230 and the 3-1 ground line 330 are greater than the distances between the 1-1 signal line 110 and a first metal line 121 at an end of the 1-1 ground line 120 and between the 1-1 signal line 110 and a second metal line 131 at an end of the 1-2 ground line 130.

Accordingly, according to Equation (1), the capacitance C reduces and the characteristic impedance Zₒ thus increases, thereby forming a high impedance. Thus, impedance matching is not influenced by the ground lines below and above the 1-1 signal line 110 (2-1 ground line 230 and 3-1 ground line 330).

According to a PCB including at least one layer and a method of manufacturing the PCB according to exemplary embodiments of the general inventive concept, the PCB may be formed to have a thin thickness, thereby increasing the yield thereof.

The present general inventive concept can also be embodied as hardware, software, or combination thereof. The present general inventive concept can also be embodied as computer-readable codes on a computer-readable medium. The computer-readable recording medium is any data storage device that can store data as a program which can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network coupled computer systems so that the computer-readable code is stored and executed in a distributed fashion. Also, functional programs, codes, and code segments to accomplish the present general inventive concept can be easily construed by programmers skilled in the art to which the present general inventive concept pertains.

Although a few exemplary embodiments of the present general inventive concept have been shown and described, it will be appreciated by those skilled in the art that changes may be made in these exemplary embodiments without departing from the principles and spirit of the general inventive concept, the scope of which is defined in the appended claims and their equivalents.

1. A printed circuit board to transmit a signal, the printed circuit board comprising:
a first layer; and
a second layer disposed on the first layer,
wherein the first layer comprises:
a first signal line to transmit the signal; and
a first ground line and a second ground line disposed at both sides of the first signal line and spaced apart from the first signal line by a first distance,
the second layer comprises:
a second signal line to transmit the signal; and
a third ground line and a fourth ground line disposed at both sides of the second signal line and spaced apart from the second signal line by a second distance, and
the third ground line or the fourth ground line is disposed above the first signal line.

2. The printed circuit board of claim 1, wherein the first distance or the second distance are adjusted to perform an impedance matching.

3. The printed circuit board of claim 1, wherein the first through the fourth ground lines are formed in a circle-hole mesh pattern.

4. The printed circuit board of claim 2, wherein the impedance matching is provided at 50Ω.

5. The printed circuit board of claim 1, further comprising a third layer disposed below the first layer, and
wherein the third layer comprises:
a third signal line to transmit the signal; and
a fifth ground line and a sixth ground line disposed at both sides of the third signal line and spaced apart from the third signal line by a third distance.

6. The printed circuit board of claim 5, wherein the fifth ground line or the sixth ground line is disposed below the first signal line.

7. The printed circuit board of claim 1, wherein the first signal line forms a first capacitance together with the first ground line and the second ground line, and
an impedance matching is performed by adjusting a value of the first capacitance by changing the first distance.

8. The printed circuit board of claim 7, wherein the first signal line forms a second capacitance together with the third ground line or the fourth ground line, and
a value of the second capacitance is less than the value of the first capacitance.

9. The printed circuit board of claim 1, wherein each of the first signal line and the second signal line comprises an inductance component.

10. The printed circuit board of claim 5, wherein the printed circuit board has a multi-layered structure including the first through the third layers.

11. A method of manufacturing a printed circuit board for transmitting a signal, the method comprising:
forming a first layer; and
forming a second layer on the first layer,
wherein the first layer comprises:
a first signal line to transmit the signal; and
a first ground line and a second ground line disposed at both sides of the first signal line and spaced apart from the first signal line by a first distance,
the second layer comprises:
a second signal line to transmit the signal; and
a third ground line and a fourth ground line disposed at both sides of the second signal line and spaced apart from the second signal line by a second distance, and
the third ground line or the fourth ground line is disposed above the first signal line.

12. The method of claim 11 further comprising adjusting the first distance or the second distance to perform an impedance matching.

13. The method of claim 11, wherein the first through the fourth ground lines are formed in a circle-hole mesh pattern.

14. The method of claim 12, wherein the impedance matching is provided at 50Ω.

15. The method of claim 11, further comprising forming a third layer below the first layer, and
wherein the third layer comprises:
a third signal line to transmit the signal; and
a fifth ground line and a sixth ground line disposed at both sides of the third signal line and spaced apart from the third signal line by a third distance.

16. The printed circuit board of claim 3, wherein each of the first through the fourth ground lines include a metal line return path,
the metal return paths of the first and second ground lines are formed between the circle-hole mesh patterns of the first and second ground lines and the first signal line, and
the metal return paths of the third and fourth ground lines are formed between the circle-hole mesh patterns of the third and fourth ground lines and the second signal line.

17. A printed circuit board to transmit a signal, the printed circuit board comprising:
a first layer including at least one first ground line and at least one first signal line to transmit the signal, the at least one first signal line being spaced a first distance from the at least one first ground line; and
a second layer disposed on the first layer in a stacked direction and including at least one second ground line and at least one second signal line to transmit the signal, the at least one second signal line being spaced a second distance from the at least one first ground line, wherein the at least one second ground line and the at least one second signal line overlap the at least one first signal line and the at least one first ground line in the stacked direction, respectively.

18. The printed circuit board of claim 17, wherein the at least one first ground line and the at least one second ground line are formed in a circle-hole mesh pattern.

19. The printed circuit board of claim 18, wherein each of the at least one first ground line and the at least one second ground line include a metal line return path,
the metal return path of the at least one first ground line is formed between the circle-hole mesh pattern of the at least one first ground line and the at least one first signal line, and
the metal return path of the at least second ground line is formed between the circle-hole mesh pattern of the at least second ground line and the at least one second signal line.

20. The printed circuit board of claim 19, wherein a first capacitance is formed between the at least first signal line and the at least one first ground line,
a second capacitance is formed between the at least first signal line and the at least one second ground line,
an impedance matching is performed by adjusting a value of the first capacitance or a value of the second capacitance by changing the first distance or the second distance, respectively, and
the value of the second capacitance is less than the value of the first capacitance.

21. (canceled)
